(19) United States
(12) Patent Application Publication
(10) Pub. No.: US 2008/0076076 A1
(43) Pub. Date: Mar. 27, 2008

(54) REWORK METHODOLOGY THAT PRESERVES GATE PERFORMANCE

(75) Inventors: Yaw Samuel Obeng, Frisco, TX (US); Yu-Tai Lee, Plano, TX (US); Rajesh Khamankar, Coppell, TX (US); April Gurba, Allen, TX (US); Brian Kirkpatrick, Allen, TX (US); Ajith Varghese, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/534,342

(22) Filed: Sep. 22, 2006

(51) Int. Cl. G03F 7/26

(52) U.S. Cl. 430/329; 430/311

(57) ABSTRACT

In one embodiment, a method of manufacturing an integrated circuit that comprises forming a circuit layer over a substrate, forming a resist layer on the circuit layer, and subjecting the resist layer to a rework process that includes exposing the resist layer to an organic wash. In another embodiment, the method of manufacturing an integrated circuit comprises forming a circuit layer over a substrate, forming a priming layer on the circuit layer, and subjecting the resist layer to the rework process. The reworking process includes exposing the substrate to a mild plasma ash to substantially remove portions of the resist layer but leave the priming layer.

### TECHNICAL FIELD

The invention is directed, in general, to integrated circuits (ICs), and more specifically, to the manufacture of ICs requiring a rework step.

### BACKGROUND

As the dimensions of components in semiconductor devices become smaller, it becomes more important to precisely define patterns in photo resists. There are numerous reasons why a photo resist pattern may not match a target pattern. E.g., changes in environmental conditions at the time of patterning, such as aging of the lamp used to expose the photo resist, or contamination of the photo resist itself, can be contributing factors.

Reworking an incorrect photo resist pattern is becoming an increasingly important part of IC fabrication. Rework processes are designed to subject a patterned photo resist layer to one or more steps to remove the photo resist without affecting the underlying layers used to form components of the IC. When the underlying layers are affected, however, the desired physical and performance characteristics of the circuit can be detrimentally altered.

Accordingly, what is needed is method of manufacturing ICs that employs a rework process in a manner that avoids altering the layers underlying the reworked photo resist layer.

### SUMMARY

One embodiment is a method of manufacturing an IC that comprises forming a circuit layer over a substrate, forming a resist layer on the circuit layer and subjecting the resist layer to a rework process that includes exposing the resist layer to an organic wash.

Another embodiment is a method of manufacturing an IC that comprises forming a circuit layer over a substrate, forming a priming layer on the circuit layer, forming a resist layer on the priming layer and subjecting the resist layer to a rework process. The rework process includes exposing the substrate to a mild plasma ash to substantially remove portions of the resist layer but leave the priming layer.

Still another embodiment is an IC that comprises one or more semiconductor devices that include a circuit layer over a substrate where the circuit layer is protected from material loss by using an organic wash as part of a rework process to remove a resist layer formed over the circuit layer.

Yet another embodiment is an IC that comprises one or more semiconductor devices that include a circuit layer over a substrate where the circuit layer is protected from material loss by a priming layer on the circuit layer during a rework process that includes a mild plasma ash configured to substantially remove a resist layer formed over the circuit layer but leave the priming layer.

### DRAWINGS

FIG. 1 illustrates a flow diagram of an example method of manufacturing an IC that comprises rework processes of the invention;

FIGS. 2 to 8 illustrate views of selected steps in example implementations of a method of fabricating an example IC 200 of the invention;

FIG. 9 illustrates an embodiment where a circuit layer has been protected from damage by using an organic wash during a rework process; and

FIG. 10 illustrates an embodiment where a circuit layer has been protected from damage by a priming layer during a rework process.

### DESCRIPTION

The invention benefits from the recognition of the source of problems encountered when the resist layer, e.g., photo sensitive resist, over a gate dielectric layer was reworked. The rework process inadvertently removed more than just the resist layer. Because portions of the underlying gate dielectric layer were removed during the rework process, a gradient of a dopant blocking material in the gate dielectric layer was altered. This, in turn, altered the physical properties and operating characteristics of transistors that were fabricated by a process that included the rework process.

Embodiments of the invention discussed herein feature the reworking of a resist on a gate dielectric layer. However, the invention is applicable to any level of a semiconductor device and could be applied at any step in an IC fabrication scheme where it is important to avoid damaging a circuit layer when an overlying layer is being reworked. A rework or reworking process is one or more process steps that restores the device to a previous point of fabrication such that processing may be resumed from that point. A circuit layer may be any layer of a semiconductor device. Example circuit layers include a gate dielectric layer, the semiconductor substrate itself (e.g., a silicon wafer), inter- or intra-metal dielectric layers, polysilicon layers, or sacrificial layers used in the fabrication of circuit components (e.g., a hard mask comprising silicon oxide).

As part of the invention, rework processes were discovered that do not substantially alter the circuit layer underlying the resist layer being reworked such that fabrication can be resumed based on that circuit layer. In some cases, including an organic wash in the rework process facilitates the removal of the resist layer without damaging the underlying circuit layer. In other cases, the underlying circuit layer is protected from damage by a priming layer located between the layer and the resist.

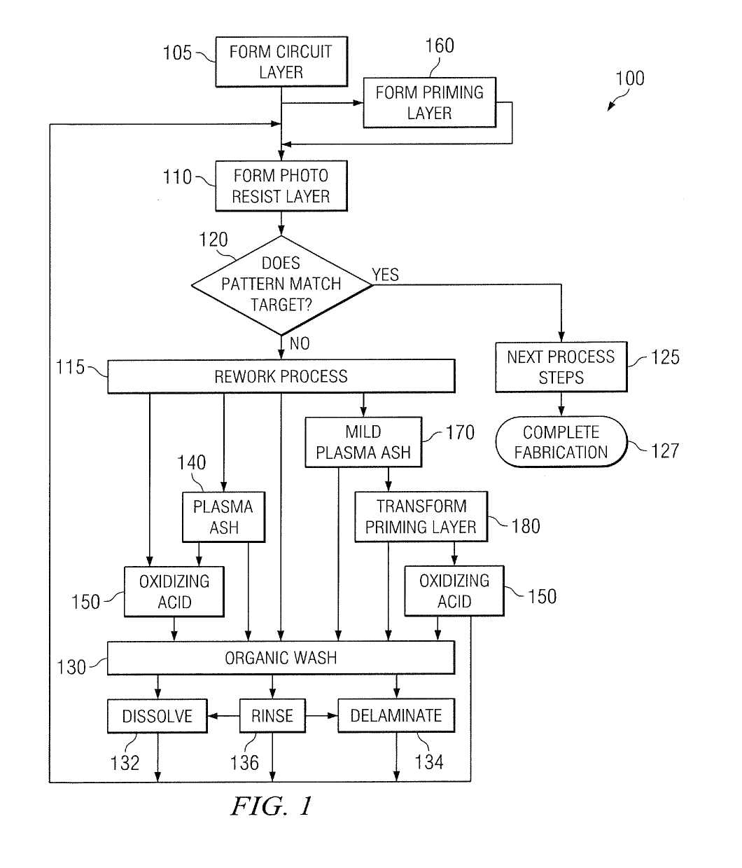

One aspect of the invention is a method of manufacturing an IC that includes one or both of the above-mentioned rework processes. FIG. 1 presents a flow diagram of an example method of manufacturing an IC that comprises rework processes of the invention.

The method 100 includes forming a circuit layer over a substrate (step 105), and forming a resist layer, e.g., a photo resist, on the circuit layer (step 110). The method also includes subjecting the resist layer to a rework process (step 115). The method can further include a decision step 120 of performing the rework process 115 if a lithographic pattern in the resist layer does not match a predetermined or target (e.g., within design specification limits) pattern. After the rework process 115, step 110 is repeated. When the lithographic pattern matches a predefined target pattern, the method 100 continues to the next process steps 125 in the manufacture of the IC (e.g., patterning the circuit layer, etc.), until the manufacture of the IC is completed at stop step 127.

In some embodiments of the method 100, the rework process 115 includes a step 130 of exposing the resist layer to an organic wash. The term organic wash as used herein refers to any solvent (e.g., liquid hydrocarbon) that is capable of disrupting the adhesion between the resist and the circuit layer. It is advantageous if resist is soluble in the organic wash because this can facilitate removal of the resist. E.g., the wash can dissolve portions of the resist layer (step 132) or delaminate the resist layer from the circuit layer (step 134), or both. In some preferred embodiments, the organic wash can be used for thinning a solution of resist for spin coating the resist onto the circuit layer.

Washing can include one or all of spraying or spin washing the substrate with the wash, or submerging the substrate in a container of the wash. One skilled in the art would appreciate that other conventional techniques to expose a semiconductor substrate to a wash could be used. The organic wash 130 may further include a rinse step 136 (e.g., a water rinse) to help remove debris (e.g., partially dissolved or delaminated resist) and excess wash from the substrate 220.

It is desirable for the wash to have a low viscosity so that it is easy to remove e.g., by centrifugal force associated with spinning the substrate. In certain embodiments, the wash has a viscosity of about 1.1 mPa·s or less at about 22° C. The wash may be a polar solvent that is soluble in water (e.g., at least about 18 g/100 g H₂O) when water is used in the rinsing step 136. E.g., preferred organic washes include low molecular weight (e.g., MW less than 500 gm/mole) alcohols, acetates, esters and ketones. In some cases, it is also advantageous if the wash is free of amines because amines left on the circuit layer after the organic wash step 130 could detrimentally alter the photo-activation properties of a post-rework-deposited resist layer. An example of an organic solvent that may comprise the wash is polypropylene glycol mono-methyl ether acetate (PGMEA).

In one embodiment, the wash 130 is performed as a last step in the rework process 115. E.g., in some cases the rework process 115 further includes one or both of a plasma ash step 140 and an oxidizing acid treatment step 150 before the organic wash step 130. The term plasma ash as used herein refers to a plasma generated on the substrate's surface that comprises an oxygen plasma and temperature of at least 200° C. for at least 30 seconds. In some cases the plasma ash includes reducing plasma ash (e.g., forming gases of H₂, N₂ or mixtures thereof) in addition to the oxygen plasma. The oxygen plasma and reducing plasma ash may be used sequentially. The term oxidizing acid treatment refers to a solution of mineral acid (e.g., sulfuric acid) and oxidizing agent (e.g., peroxide or ozone) at about 120° C. for up to 50 minutes, water rinse (e.g., about 10 to 30 minutes), followed by a wash with a mixture of ammonium hydroxide and hydrogen peroxide. One advantage of including a plasma ash or oxidizing acid treatment in the rework process 115 is that the bulk of the resist layer (e.g., about 50 to 90 percent) can be removed by these steps 140, 150, thereby allowing less organic solvent to be used in the washing step 130. This, in turn, helps reduce the costs and environmental impact of using and disposing organic solvents.

Another embodiment of the method 100 includes forming a priming layer on the circuit layer (step 160). The term priming layer as used herein refers to any physical layer deposited on a circuit layer that increases the adhesion of a resist layer to the circuit layer. In some cases, the priming layer is a silicon-containing material comprising hexamethyldisiloxane. For example the priming layer can comprise a polymer derived from dimethyldichlorosilane, (CH₃)₂SiCl₂, the molecular weight of such polymers being controlled by the use of chain-termination agent comprising a hexamethyldisiloxane derivative. An example process for making a priming layer can be represented by the following equation:

[Me₂SiO]ₙ+Me₃SiOSiMe₃→Me₃SiO[Me₂SiO]ₙSiMe₃

where [Me₂SiO]ₙ represents the dimethyldichlorosilane-derived polymer, Me₃SiOSiMe₃ corresponds to hexamethyldisiloxane and Me₃SiO[Me₂SiO]ₙSiMe₃ represents the polymer of the priming layer. One skilled in the art would be familiar with other suitable adhesion-promoting materials that could be used.

As an alternative, or in addition, to the organic wash (step 130), the rework process 115 includes a mild plasma ash step 170 that substantially removes the resist layer, but leaves the priming layer. The term mild plasma ash as used herein refers to an oxygen plasma having a thermal budget (e.g., temperature substrate multiplied by the duration of the ash) ranging from about 800 to 9000 s·° C., with a temperature range of about 80° C. to 100° C. and a duration of about 10 to 90 seconds. The term substantially remove as used herein refers to the removal of at least about 10 percent of the resist layer.

In embodiments where the substrate is then exposed to an oxidizing acid treatment step 150, to e.g., remove remaining portions of the resist layer, the priming layer prevents material losses from the circuit layer. The term material losses as used herein, refers to any physical change in the circuit layer, including a reduction in its thickness, or a change in dopant concentrations in all or a portion of the layer, as compared to the priming layer before the oxidizing acid treatment step 150. In certain embodiments, the mild plasma ash step 170 modifies the priming layer (step 180) so as to increase the priming layer's resistance to removal by the oxidizing acid treatment step 150, as compared to a virgin priming layer, that is, a priming layer that has not been exposed to the mild plasma ash step 170.

A rework process 115 that involves the use of a mild plasma ash step 170, can be advantageous in situations where a more aggressive plasma ash (e.g., plasma ash step 140) would alter the properties of the circuit layer. E.g., in some embodiments, when the circuit layer comprises a high-k dielectric material, e.g., tantalum pentoxide (Ta₂O₃), the circuit layer can be activated by the plasma ash 140, resulting in a change in the dielectric properties due to the creation of point-defects in the dielectric layer by the high energy particles in an aggressive plasma.

In some cases, a rework process 115 uses the priming layer to protect the circuit layer and does not require the use of the organic wash step 130. This can be advantageous in embodiments whether the circuit layer itself comprises an organic material that is soluble in, or could be delaminated by, the organic wash. E.g., the circuit layer can comprise an organic dielectric material, including carbon-doped oxides, such as black-diamond IIx (BD-IIx) (Applied Materials Inc., Santa Clara, Calif.). The use of the priming layer without the organic wash can also be advantageous in embodiments whether the organic wash could remove the priming layer. E.g., because the priming layer remains on the circuit layer after the rework process, there is no need to apply a new priming layer before applying a new resist layer.

In other cases, however, the use of a rework process 115 that involves the use of the wash 130 can be advantageous when it is desirable or unnecessary to form a priming layer. A rework process 115 that uses the wash 130 is also advantageous in instances where it is undesirable to also use one or all of the plasma ash 140, the oxidizing acid treatment step 150, or the mild plasma ash 170.

In still other cases, however, the rework process 115 can include both the wash 130 and protection via forming the priming layer (step 160), and the acid oxidizing treatment 150 is optional. In some embodiments, e.g., the wash 130 leaves the priming layer on the circuit layer. E.g., when the wash 130 comprises PGMEA, and the priming layer comprises hexamethyldisiloxane, the wash 130 leaves the priming layer on the circuit layer.

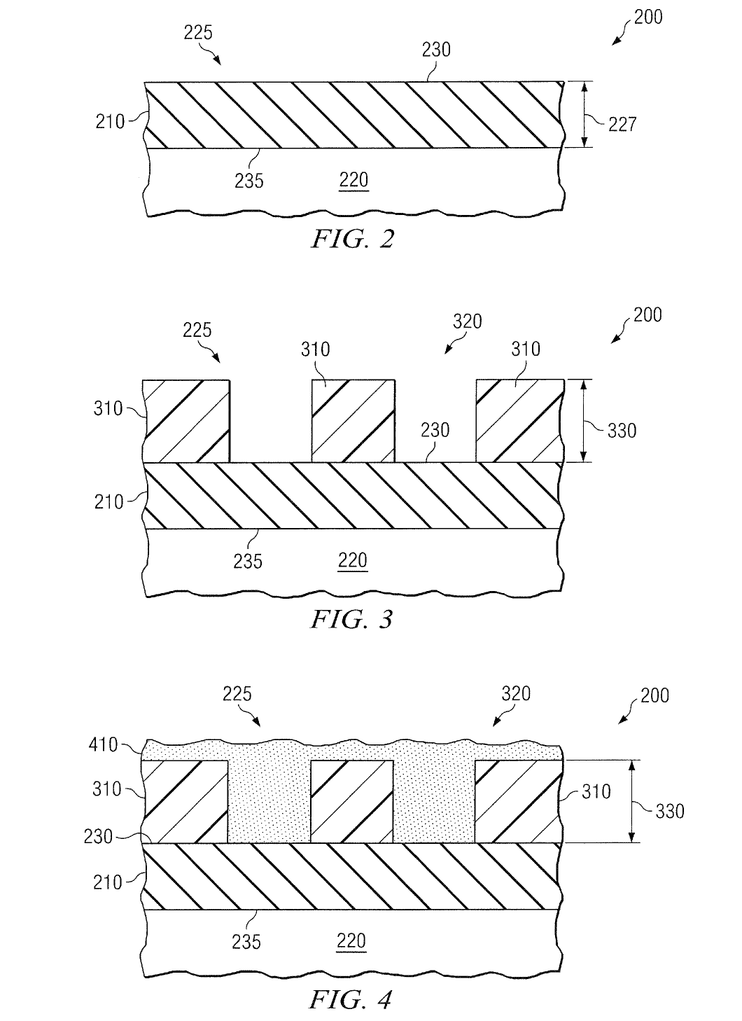

To further illustrate additional aspects of the method presented in FIG. 1, FIGS. 2 to 8 illustrate cross-section views of selected steps in example implementations of a method of fabricating an example IC 200 of the invention.

FIG. 2 shows the IC 200 after forming a circuit layer 210 over, and in some cases on, a substrate 220, in accordance with step 105 (FIG. 1). In some cases, the circuit layer 210 comprises a gate dielectric layer that comprises silicon oxide, and the substrate 220 comprises a semiconductor wafer, such as a silicon wafer. The circuit layer 210 can be a component in a semiconductor device 225 of the IC 200. E.g., the circuit layer 210 can comprise a gate dielectric layer in a metal oxide semiconductor (MOS) device 225, such as a pMOS or nPMOS transistor.

In some cases, the circuit layer 210 comprises a nitrided gate dielectric layer. One skilled in the art would be familiar with methods to dope a dielectric layer with nitrogen using, e.g., decoupled plasma nitridation processes, or other conventional processes. The nitrogen atoms of the dielectric layer serve as dopant blocking materials to deter the passage of contaminants from an overlying circuit layer into the circuit layer 210 or underlying layers. In some cases, e.g., the nitrogen atoms block the passage of boron from an overlying polysilicon gate layer to the gate dielectric layer or underlying substrate. In other embodiments, the circuit layer 210 comprises a silicon oxide layer doped with nitrogen such that there is a gradient of nitrogen concentration in the thickness 227 of the gate dielectric layer. E.g., there can be an exponentially increasing concentration of nitrogen from the top surface 230 (the surface facing away from the substrate 220) of the circuit layer 210 to the bottom surface 235 (the surface facing the substrate 220) of the layer 210.

FIG. 3 shows the IC 200 after forming a resist layer 310 over the circuit layer 210 in accordance with step 110 (FIG. 1). For the embodiment shown, the resist 310 is formed on the circuit layer 210. The resist 310 can comprise any photosensitive material that, when applied to a substrate and exposed to ultraviolet, visible, other wavelengths of light or an electron beam, can develop into a lithographic mask pattern 320 over the substrate 220. One of ordinary skill in the art would be familiar with the types and amounts of resist material that can be used.

For the purposes of illustration, it is assumed that in a decision step 120 (FIG. 1), it is determined that the lithographic mask pattern 320 does not match a predefined target pattern, and therefore, the substrate 220 is subject to a rework process in accordance with step 115 (FIG. 1).

FIG. 4 shows the IC 200 while subjecting the resist layer 310 to a rework process (step 115 in FIG. 1) that includes exposing the resist layer 310 to an organic wash 410, in accordance with step 130 (FIG. 1). As illustrated, washing with the organic wash 410 can partially dissolve the resist layer 310 or delaminate the resist layer 310 from the circuit layer 210, in accordance with steps 132 and 134, respectively. In some embodiments, washing with the organic wash 410 includes spin washing the substrate 220, and its resist layer 310, with PGMEA for about 1 to 10 minutes, at room temperature (20-25° C.). One skilled in the art would understand how the wash 410 could be adjusted to remove thicker or different types of resist material. E.g., longer wash times, higher temperatures, and greater spin rates could be selected to facilitate removal of a thicker resist layer 310. In other cases, the substrate 220 can be placed in a container (e.g., a bath) holding the wash 410, or the substrate 220 is sprayed with the wash 410.

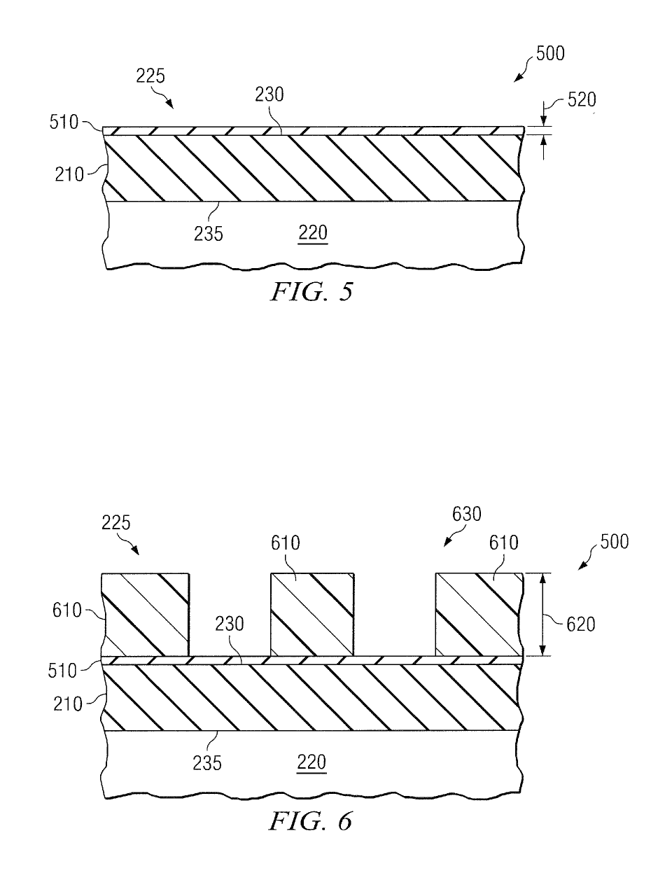

FIGS. 5-8 (using similar reference numbers to FIG. 2) shows an example IC 500 whose resist layer is subject to a rework process 115, in accordance with steps 160 and 170, and optional step 180 (FIG. 1). FIG. 5 shows the IC 500 after forming a circuit layer 210 over or on a substrate 220, in accordance with step 105, and after forming a priming layer 510 on the circuit layer 210. E.g., in some embodiments, forming the priming layer 510 comprises coating (e.g., spin coating) the top surface 230 of the circuit layer 210 with hexamethyldisiloxane. In certain embodiments, the priming layer's thickness 520 ranges from a few molecular layers (e.g. about 1 nanometer) to about 1 micron. In some cases, it is undesirable for the priming layer's thickness 520 to exceed 1 micron, because it is then difficult to form a priming layer 510 of uniform thickness 520.

FIG. 6 shows the IC 200 after forming a resist layer 610 of thickness 620 on the priming layer 510, in accordance with step 110 (FIG. 1). The resist layer 610 can comprise the same types of photosensitive material as discussed in the context of FIG. 3. In some cases, the resist layer 610 does not adhere strongly to the circuit layer 210, and therefore benefits from the use of the priming layer 510 to promote adhesion. Again, for the purposes of illustration, it is assumed that in decision step 120 (FIG. 1), it is determined that a lithographic mask pattern 630 of the resist layer 610 does not match a predefined target pattern, and therefore the substrate 220 is subject to a rework process in accordance with step 115 (FIG. 1).

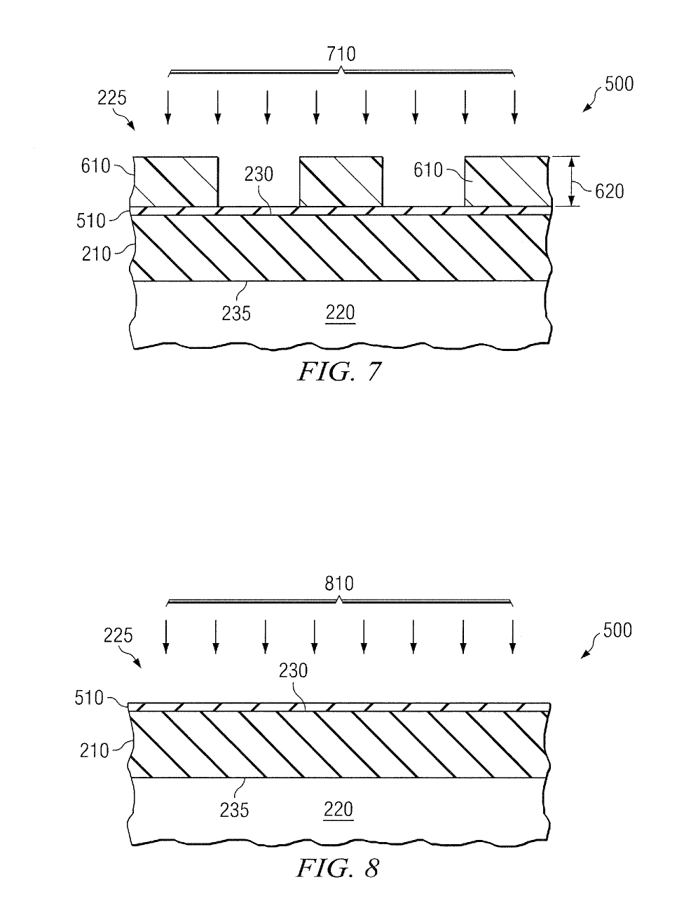

FIG. 7 shows the IC 200 after subjecting the resist layer 610 to a rework process (step 115 in FIG. 1) that includes exposing the substrate 220 to a mild plasma ash 710 to substantially remove portions of the resist layer 610, but leaves the priming layer 510, in accordance with step 170 (FIG. 1). In some cases, about 10 to 50 percent of the thickness 620 of the resist layer 610 is removed by the mild plasma ash 710. In certain embodiments, the mild plasma ash 710 comprises a thermal budget (e.g., temperature substrate multiplied by the duration of the ash) ranging from about 800 to 900 s·° C., with a temperature range of about 80° C. to 90° C. and a duration of about 10 to 15 seconds. One skilled in the art would be familiar with the measurement techniques available to confirm the presence of the priming layer 510 on the circuit layer 210 after the mild plasma ash 710. E.g., time-of-flight secondary ion mass spectroscopy (TOF SIMS) can be used to identify the priming layer 510, based on the pattern of secondary elemental or cluster ions emitted from the priming layer 510.

FIG. 8 shows the IC 200 after exposing the substrate 220 to an oxidizing acid treatment 810, in accordance with step 150, to remove remaining portions of the resist layer 610 (FIG. 7). The presence of the priming layer 510 prevents material losses from the circuit layer 210. Consider, e.g., the case where the circuit layer 210 comprises a nitrided gate dielectric. Preventing material loss from the circuit layer 210 comprises preventing the loss of nitrogen from the nitrided gate dielectric layer. While not limiting the scope of the invention by theory it is believed that the priming layer 510 prevents reactants of the oxidizing acid treatment 810 from contacting the nitrided gate dielectric layer 210. In some embodiments, the priming layer 510 is not removed by the oxidizing acid treatment. E.g., TOF SIMS measurements can be used to confirm the presence of the priming layer 510 on the circuit layer 210.

In some cases, the mild plasma ash 710 (FIG. 7) increases the priming layer's 510 resistance to removal by the oxidizing acid treatment 810, as compared to a virgin priming layer 510 (FIGS. 5 or 6) that has not been exposed to the mild plasma ash 710. That is the priming layer 510 is transformed to be more resistant to the oxidizing acid treatment 810, in accordance with step 180 (FIG. 1). This beneficially improves the priming layer's 510 ability protect the circuit layer 210 during the oxidizing acid treatment 810.

One skilled in the art would appreciate that there are several ways to confirm the priming layer's 510 resistance to removal by the oxidizing acid treatment 810. TOF SIMS measurements can be used to confirm the presence of a mild-plasma-ash-treated priming layer 510 (FIG. 7) after the oxidizing acid treatment 810, but the absence of a virgin priming layer 510 (FIG. 5 or 6) after the oxidizing acid treatment 810. Or, when the circuit layer 210 comprises a nitrided gate dielectric layer, the surface nitrogen content of the circuit layer 210 can be measured and compared to a target value. E.g., the surface nitrogen content of the circuit layer 210 remains within about 15 percent of a target value or in another embodiment, remains within about 5 percent, when the overlying priming layer 510 is exposed to the mild plasma ash 710 (FIG. 7) and then the oxidizing acid treatment 810 for 40 minutes. In comparison, the surface nitrogen content of the circuit layer 210 can be more than about 15 percent lower than a target value when a virgin priming layer 510 (FIG. 6), not subjected to the mild plasma ash 710, is then exposed to the oxidizing acid treatment for 40 minutes.

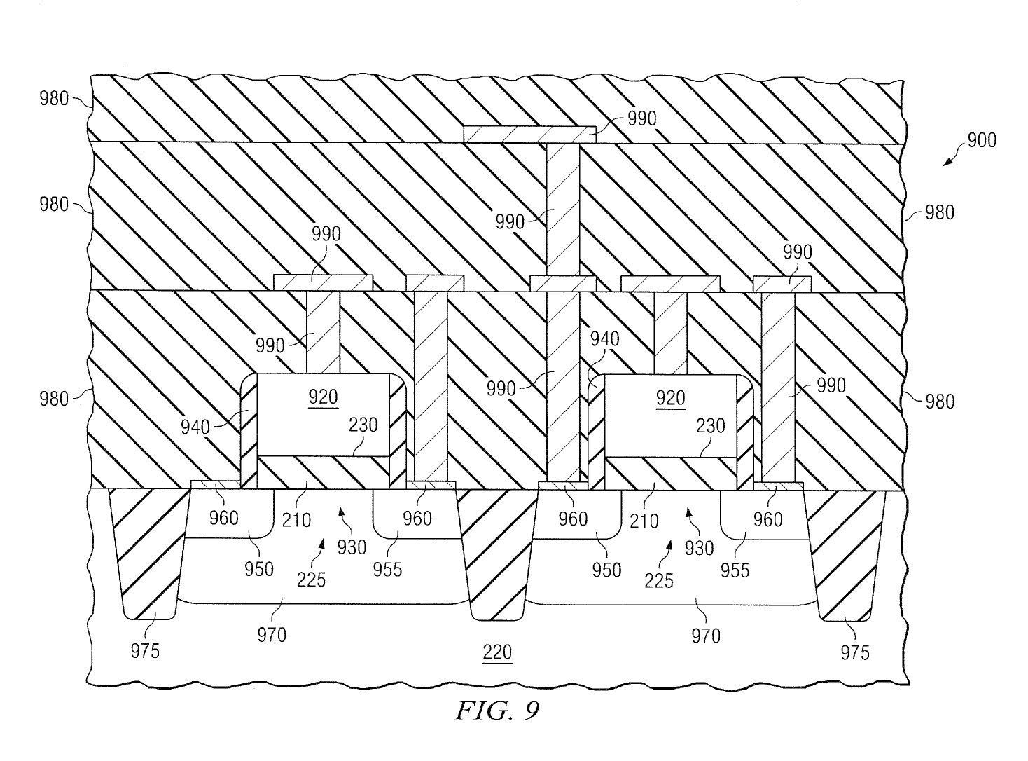

Another aspect of the invention is an IC that is manufactured by a method that includes any of the above-described rework processes. With continuing reference to as FIGS. 2-8 (and using the using the same reference numbers), FIG. 9 shows a cross-sectional view of an example IC 900 of the present invention, but at lower magnification. The IC 900 comprises one or more semiconductor devices 225 (e.g., pMOS or nMOS transistors) that include a circuit layer 210 over a substrate 220. The circuit layer 210 is protected from material loss by using an organic wash as part of a rework process to remove a resist layer 310 (FIG. 3) formed over the circuit layer 210. E.g., the substrate 220 and overlaying circuit layer 210, and resist layer 310 were subjected to a rework process 115 that includes an organic wash 130 to remove the resist layer 310 such as described in the context of step 130 (FIG. 1) and FIG. 4.

Referring to FIG. 1, if after the rework process 115, the lithographic mask pattern 320 (FIG. 3) matches a predefined target pattern, processing of the IC 900 continues to the next process steps 125 until the IC 900 is completed (stop step 127). E.g., in the case where the circuit layer 210 comprises a gate dielectric layer, as illustrated in FIG. 9, the next process steps 125 can include depositing a polysilicon gate layer 920 on the gate dielectric layer 210. The polysilicon gate layer 920 and gate dielectric layer 210 may then be patterned to form a gate 930. One skilled in the art would be familiar with the conventional processes used to form other components of the IC 900 including, gate sidewalls 940, source and drain regions, 950, 955, source and drain electrodes 960, doped well 970, isolation structures 975, insulation layers 980 and interconnect structures 990, and other circuit components needed to complete the IC 900.

In embodiments, where the circuit layer 210 comprises a nitrided gate dielectric layer, the nitrided gate dielectric layer has a surface 230 nitride layer with a nitrogen content ranging from about 4 to 7 E15 Nitrogen atoms/cm². In such embodiments, the surface nitrogen content after the rework process remains within ±15 percent (and more preferably ±5 percent ore less) of the nitrogen content before the rework process.

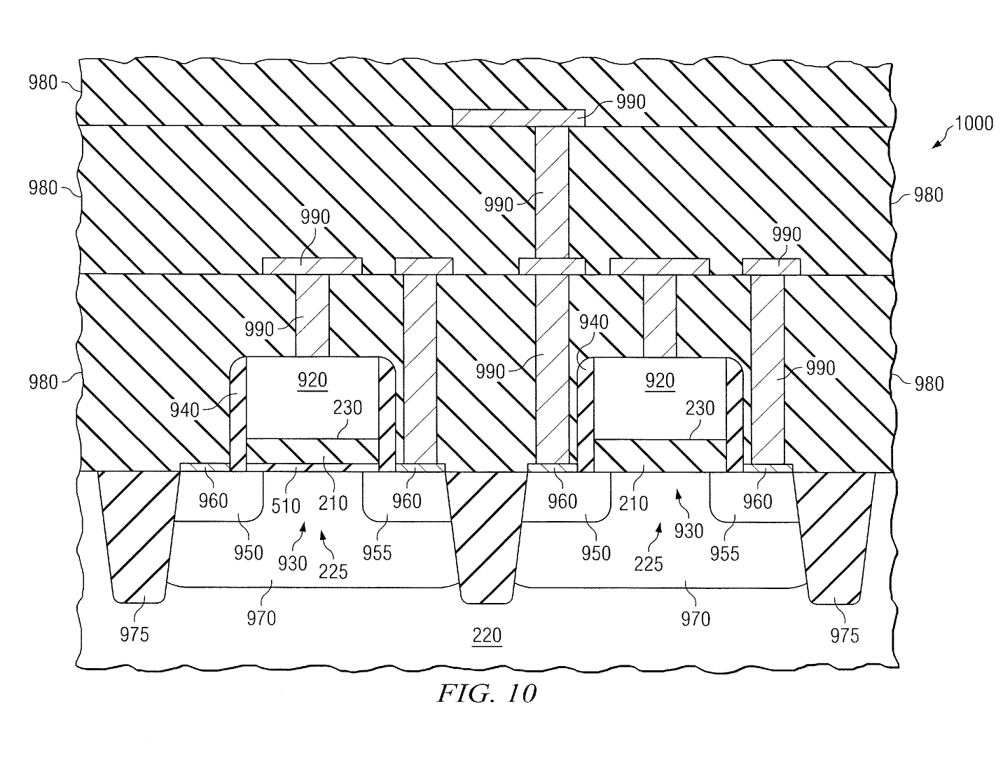

FIG. 10 shows a cross-sectional view of another example IC 1000 of the present invention. FIG. 10 shows a cross-sectional view of an example IC 1000 of the present invention. The IC 1000 comprises one ore more semiconductor devices 225 (e.g., a pMOS or nMOS transistor), which includes a circuit layer 210 over a substrate 220. The circuit layer 210 is protected from material loss by a priming layer 510 on the circuit layer 210 during a rework process that includes a mild plasma ash and oxidizing acid treatment configured to remove a resist layer 310 formed on the circuit layer 210, but leaves the priming layer 510. Analogous to that discussed above in the context of FIG. 9, it is assumed that steps 120, 125 and 127 (FIG. 1) are conducted to complete the fabrication of the IC 1000.

In some embodiments, the circuit layer 210 includes organic material. E.g., the circuit layer 210 can comprise an organic dielectric layer. In other embodiments, the circuit layer 210 comprises a nitrided gate dielectric layer on the substrate 220. In some cases the circuit layer 210 comprises a nitrided organic dielectric layer. In these instances, a surface nitride layer 230 of the circuit layer 210 has a nitrogen content after the rework process that remains within ±15 percent (and more preferably ±5 percent ore less) of a nitrogen content before the rework process.

As illustrated in FIG. 10, the IC 1000 can include the priming layer 510 in its final structure. E.g., the IC 1000 can include a priming layer 510 that comprises hexamethyldisiloxane or a derivative thereof. Similarly, embodiments of the IC 1000 that are subject to a rework process that includes the organic wash can also include a priming layer, similar to that depicted in FIG. 10.

Those skilled in the art to which the invention relates will appreciate that other and further additions, deletions, substitutions and modifications may be made to the described example embodiments, without departing from the invention.

1. A method of manufacturing an integrated circuit, comprising:
forming a circuit layer over a substrate;
forming a resist layer on said circuit layer; and
subjecting said resist layer to a rework process that includes exposing said resist layer to an organic wash.

2. The method of claim 1, wherein said organic wash is performed as a last step in said rework process.

3. The method of claim 1, wherein said resist layer is a first photo resist that does not match a predetermined pattern and subjecting includes removing said first photo resist to expose said circuit layer, and the method further includes forming and patterning a second photo resist on said circuit layer and using said second photo resist to form a subsequent layer on said circuit layer.

4. The method of claim 1, wherein said rework process includes one or both of a plasma ash or an oxidizing acid treatment before said organic wash.

5. The method of claim 1, wherein said circuit layer comprises a gate dielectric layer.

6. The method of claim 1, wherein said organic wash includes one or more polar organic solvents having a viscosity of about 1.1 mPa·s or less at about 22° C.

7. The method of claim 1, further including forming a priming layer on said circuit layer and subjecting said resist to said organic wash includes leaving said priming layer.

8. A method of manufacturing a semiconductor device, comprising:
forming a circuit layer over a substrate;
forming a priming layer on said circuit layer;
forming a resist layer on said priming layer; and
subjecting said resist layer to a rework process that includes exposing said substrate to a mild plasma ash to substantially remove portions of said resist layer but leave said priming layer.

9. The method of claim 8, wherein said rework process further includes exposing said substrate to an oxidizing acid treatment to remove remaining portions of said resist layer, wherein said priming layer prevents material losses from said circuit layer.

10. The method of claim 8, wherein said mild plasma ash increases said priming layer's resistance to removal by said oxidizing acid treatment as compared to a virgin priming layer that has not been exposed to said mild plasma ash.

11. The method of claim 8, wherein said rework process further includes exposing said substrate to an organic wash.

12. The method of claim 8, wherein said mild plasma ash includes an oxygen plasma having a thermal budget of about 800 to 9000 s·° C., a temperature range of about 80 to 100° C. and a duration of about 10 to 90 seconds.

13. An integrated circuit, comprising:
one or more semiconductor devices, including:
a circuit layer over a substrate, wherein said circuit layer has been protected from material loss by using an organic wash as part of a rework process to remove a resist layer formed over said circuit layer.

14. The circuit of claim 1, wherein said circuit layer comprises a nitrided gate dielectric layer on said substrate.

15. The circuit of claim 13, wherein said nitrided gate dielectric layer has a surface nitride layer with a nitrogen content ranging from about 4 to 7 E15 Nitrogen atoms/cm².

16. The circuit of claim 15, wherein said nitrogen content after said rework process remains within ±15 percent of a nitrogen content before said rework process.

17. An integrated circuit, comprising:
one or more semiconductor devices, including:
a circuit layer located over a substrate, wherein said circuit layer is protected from material loss by a priming layer on said circuit layer during a rework process that includes a mild plasma ash configured to substantially remove a resist layer formed over said circuit layer but leaves said priming layer.

18. The circuit of claim 16, wherein said circuit layer includes organic material.

19. The circuit of claim 16, wherein said priming layer comprises hexamethyldisiloxane or a derivative thereof.

20. The device of claim 19, wherein said circuit layer comprises a nitrided gate dielectric layer on said substrate and a surface nitride layer of said circuit layer has a nitrogen content that remains within ±15 percent of a nitrogen content before said rework process that further includes an oxidizing acid treatment.
